(19) United States
(12) Patent Application Publication
(10) Pub. No.: US 2011/0057322 A1
(43) Pub. Date: Mar. 10, 2011

(54) CARBON NANOTUBE INTERCONNECT AND METHOD OF MANUFACTURING THE SAME

(76) Inventors: Noriaki MATSUNAGA, Chigasaki-shi (JP); Makoto Wada, Yokohama-shi (JP); Yosuke Akimoto, Yokohama-shi (JP); Tadashi Sakai, Yokohama-shi (JP); Naoshi Sakuma, Yokohama-shi (JP); Masayuki Katagiri, Kawasaki-shi (JP); Yuichi Yamazaki, Inagi-shi (JP)

(21) Appl. No.: 12/876,669

(22) Filed: Sep. 7, 2010

(30) Foreign Application Priority Data
Sep. 10, 2009 (JP) 2009-209527

(51) Int. Cl. H01L 23/522; H01L 21/768

(52) U.S. Cl. 257/774; 438/618; 977/742; 257/E23.145; 257/E21.586

(57) ABSTRACT

According to one embodiment, a carbon nanotube interconnect includes a first interconnection layer, an interlayer dielectric film, a second interconnection layer, a contact hole, a plurality of carbon nanotubes and a film. The interlayer dielectric film is formed on the first interconnection layer. The second interconnection layer is formed on the interlayer dielectric film. The contact hole is formed in the interlayer dielectric film between the first interconnection layer and the second interconnection layer. The carbon nanotubes are formed in the contact hole. The carbon nanotubes have a first end connected to the first interconnection layer and a second end connected to the second interconnection layer. The film is formed between the interlayer dielectric film and the second interconnection layer. The film has a portion filled between the second ends of the carbon nanotubes.

### CROSS-REFERENCE TO RELATED APPLICATIONS

This application is based upon and claims the benefit of priority from Japanese Patent Application No. 2009-209527, filed Sep. 10, 2009; the entire contents of which are incorporated herein by reference.

### FIELD

Embodiments described herein relate generally to a carbon nanotube interconnect and a method of manufacturing the same.

### BACKGROUND

A carbon nanotube (CNT) causes ballistic conduction parallel to the tube surface, and hence is expected to provide a low-resistance interconnect regardless of its length. Also, in a multi-walled carbon nanotube (MWCNT) having several layers of tube walls, electric currents equal in number to the walls flow. Letting R be the resistance of a single-walled carbon nanotube, therefore, the resistance value of the MWCNT is R/n (n is the number of walls).

### BRIEF DESCRIPTION OF THE DRAWINGS

FIGS. 1A and 1B are sectional views showing a carbon nanotube plug interconnect of a first embodiment;

FIGS. 2A to 3C are sectional views showing a method of manufacturing the carbon nanotube plug interconnect of the first embodiment;

FIGS. 4A and 4B are sectional views showing a carbon nanotube plug interconnect of a second embodiment;

FIGS. 5A to 6B are sectional views showing a method of manufacturing the carbon nanotube plug interconnect of the second embodiment;

FIGS. 7A to 7C are sectional views showing a method of manufacturing a carbon nanotube plug interconnect of a modification of the second embodiment;

FIGS. 8A to 8D are sectional views showing the method of manufacturing the carbon nanotube plug interconnect of the modification of the second embodiment;

FIGS. 9A to 10C are sectional views showing a method of manufacturing a carbon nanotube plug interconnect of a third embodiment;

FIGS. 11A to 12B are sectional views showing a method of manufacturing a carbon nanotube plug interconnect of a modification of the third embodiment;

FIGS. 13A and 13B are sectional views showing a carbon nanotube plug interconnect of a fourth embodiment;

FIGS. 14A to 15C are sectional views showing a method of manufacturing the carbon nanotube plug interconnect of the fourth embodiment;

FIGS. 16A and 16B are sectional views showing a carbon nanotube plug interconnect of a fifth embodiment;

FIGS. 17A to 18B are sectional views showing a method of manufacturing the carbon nanotube plug interconnect of the fifth embodiment;

FIGS. 19A and 19B are sectional views showing a carbon nanotube plug interconnect of a sixth embodiment; and

FIGS. 20A to 21B are sectional views showing a method of manufacturing the carbon nanotube plug interconnect of the sixth embodiment.

### DETAILED DESCRIPTION

Embodiments will be explained below with reference to the accompanying drawing. In the following explanation, the same reference numerals denote the same parts throughout the drawing.

In embodiments, in a multilayered interconnection structure including first and second interconnection layers and an interlayer dielectric film formed between the first and second interconnection layers, a plug interconnect for electrically connecting the first and second interconnection layers is formed in the interlayer dielectric film. The plug interconnect has carbon nanotubes formed in a contact hole in the interlayer dielectric film.

In general, according to one embodiment, a carbon nanotube interconnect includes a first interconnection layer, an interlayer dielectric film, a second interconnection layer, a contact hole, a plurality of carbon nanotubes and a film. The interlayer dielectric film is formed on the first interconnection layer. The second interconnection layer is formed on the interlayer dielectric film. The contact hole is formed in the interlayer dielectric film between the first interconnection layer and the second interconnection layer. The carbon nanotubes are formed in the contact hole. The carbon nanotubes have a first end connected to the first interconnection layer and a second end connected to the second interconnection layer. The film is formed between the interlayer dielectric film and the second interconnection layer. The film has a portion filled between the second ends of the carbon nanotubes.

### (1) Problems of End Opening

A carbon nanotube (CNT) causes ballistic conduction parallel to the tube surface, and hence is expected to provide a low-resistance interconnect regardless of its length. Also, in a multi-walled carbon nanotube (MWCNT) having several layers of tube walls, electric currents equal in number to the walls flow. Letting R be the resistance of a single-walled carbon nanotube, therefore, the resistance value of the MWCNT is R/n (n is the number of walls).

On the other hand, conduction from the wall to the wall of the carbon nanotube experiences a very high resistance. When growing the MWCNT, the terminal end of the growth is generally closed in the form of a dome. Even when the growth height of the MWCNT is ideally uniform and the upper surface of the MWCNT is in contact with an interconnection metal, an electric current crossing several layers of sidewalls need to be supplied in order to use parallel conduction paths inside the MWCNT.

In addition, the length of the MWCNT has variations in practice, and a portion extending from the opening of a via falls or inclines in the lateral direction. Consequently, an upper interconnection metal is in contact with the sidewalls of the MWCNT.

This poses the problem that it is impossible to fully utilize the merit of a low resistance of the MWCNT. This problem decreases the efficiency from the viewpoint of not only a low resistance but also a current density durability: the current density decreases because not all the walls in the MWCNT can be used in conduction.

To solve these problems, it is possible to destroy the crystal structure at the end of the MWCNT (an end-opening process), and form a connection by which an upper interconnect is in contact with multilayered wall surfaces inside the MWCTN. Examples of this end-opening process are a method of destroying the structure by irradiation with an energy line such as a plasma, UV light, or an ion beam, and a method of opening the end by a reaction with a chemical species or radical such as oxygen, hydrogen, or fluorine.

Unfortunately, there are spaces between individual carbon nanotubes. If any of these end-opening processes is performed on an actual carbon nanotube interconnection structure, therefore, the crystal structure is destroyed in portions other than the end of the carbon nanotube to be opened. Furthermore, the surface of a first interconnect as the root of the carbon nanotube sometimes changes.

(2) Excess Growth from Hole and Difficulty in Removal by Chemical Mechanical Polishing

When growing carbon nanotubes in a via hole or contact hole, the carbon nanotubes sometimes grow to protrude from the hole, and these excess carbon nanotubes are removed by using chemical mechanical polishing (CMP) or the like. Since the carbon nanotubes have a low CMP rate, however, an interlayer dielectric film is polished, and the carbon nanotubes remain as dust on the interlayer dielectric film.

Also, there is a method of coating the carbon nanotubes with spin-on-glass (SOG) and performing CMP in order to fix the carbon nanotubes (see, e.g., JP 2008-41954). Generally, however, the CMP rate of the SOG is high, and the carbon nanotubes are hard to polish. Therefore, the carbon nanotubes are dragged or pulled out from a hole. Alternatively, while the carbon nanotubes are not polished at all, only the SOG and the underlying interlayer dielectric film are polished, and the carbon nanotubes just fall. If a second interconnect is formed on the carbon nanotubes in this state, a pattern defect occurs or dust causes an electrical defect.

It is also possible to remove the excess portions of the carbon nanotubes by using plasma etching instead of CMP. As described in “(1) Problems of End Opening”, however, damage may be inflicted not only to the ends of the carbon nanotubes, but also to the side walls of the carbon nanotubes or an interconnect below the carbon nanotubes.

### [1] First Embodiment

In the first embodiment, an example in which an insulating film as a stopper film is formed on an interlayer dielectric film having a plug interconnect and a second interconnection layer is formed in an etching step will be explained. In a CMP step of polishing carbon nanotubes protruding from a contact hole, the insulating film on the interlayer dielectric film functions as a stopper film and fixes the carbon nanotubes. The carbon nanotubes are held by the stopper film.

### [1-1] Carbon Nanotube Plug Interconnect

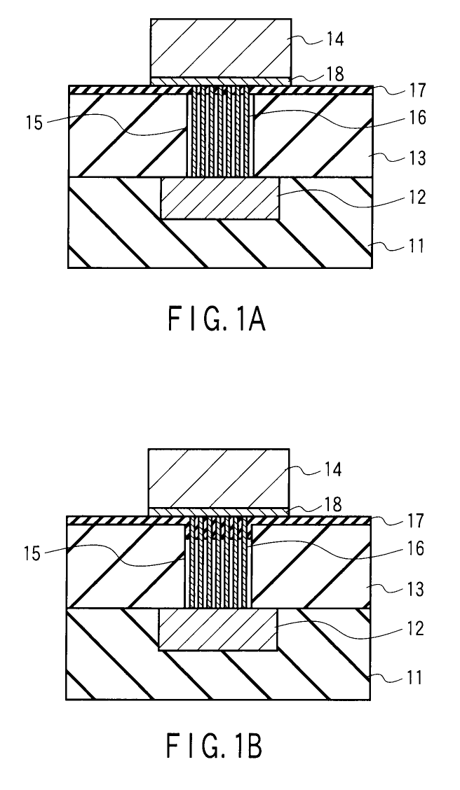

FIG. 1A is a sectional view showing a carbon nanotube plug interconnect of the first embodiment.

As shown in FIG. 1A, a first interconnection layer 12 is formed in an interlayer dielectric film 11. The interlayer dielectric film 11 is made of, e.g., SiO₂ or SiOC, and formed on a semiconductor substrate (not shown). The first interconnection layer 12 is made of, e.g., Cu, and buried in the interlayer dielectric film 11. The top surface of the first interconnection layer 12 is exposed from the interlayer dielectric film 11.

A barrier metal (not shown) is formed between the first interconnection layer 12 and the interlayer dielectric film 11 as needed. The barrier metal is made of at least one of, e.g., Ta, TaN, Ti, and TiN, or a multilayered film of these metals.

An interlayer dielectric film 13 is formed on the interlayer dielectric film 11 and the first interconnection layer 12. The interlayer dielectric film 13 is made of, e.g., SiO₂ or SiOC.

In the interlayer dielectric film 13 on the first interconnection layer 12, a contact hole 15 for electrically connecting the first interconnection layer 12 and a second interconnection layer 14 to be formed on the interlayer dielectric film 13 is formed. Carbon nanotubes 16 are formed in the contact hole 15. The carbon nanotubes 16 electrically connect the first interconnection layer 12 and the second interconnection layer 14. The second interconnection layer 14 is made of, e.g., Al.

A stopper film 17 is formed on the interlayer dielectric film 13. The stopper film 17 is filled in the ends of the carbon nanotubes 16 on the side of the second interconnection layer 14, so as to fix the carbon nanotubes 16. The stopper film 17 is made of an insulating film, e.g., SiN, SiC, or SiCN, and also has the effect of cutting ultraviolet (UV) radiation. The stopper film 17 can also be a multilayered film of SiN and SiO₂, or a multilayered film of SiN and SiOC.

A barrier metal 18 is formed between the stopper film 17 and second interconnection layer 14. The carbon nanotubes 16 each have one end in contact with the first interconnection layer 12, and the other end in contact with the barrier metal 18. The first interconnection layer 12 and second interconnection layer 14 are electrically connected via the carbon nanotubes 16. The barrier metal 18 is made of at least one of, e.g., Ta, TaN, Ti, and TiN, or a multilayered film of these metals.

Note that FIG. 1A shows an example in which the stopper film 17 is formed at the ends of the carbon nanotubes 16 on the side of the second interconnection layer 14, from the bottom surface of the barrier metal 18 to that of the stopper film 17. However, as shown in FIG. 1B, the stopper film 17 can also be formed from the bottom surface of the barrier metal 18 to a position deeper than the bottom surface of the stopper film 17. That is, the stopper film 17 may be protruded to the contact hole 15 from the bottom surface of the barrier metal 18.

### [1-2] Method of Manufacturing Carbon Nanotube Plug Interconnect

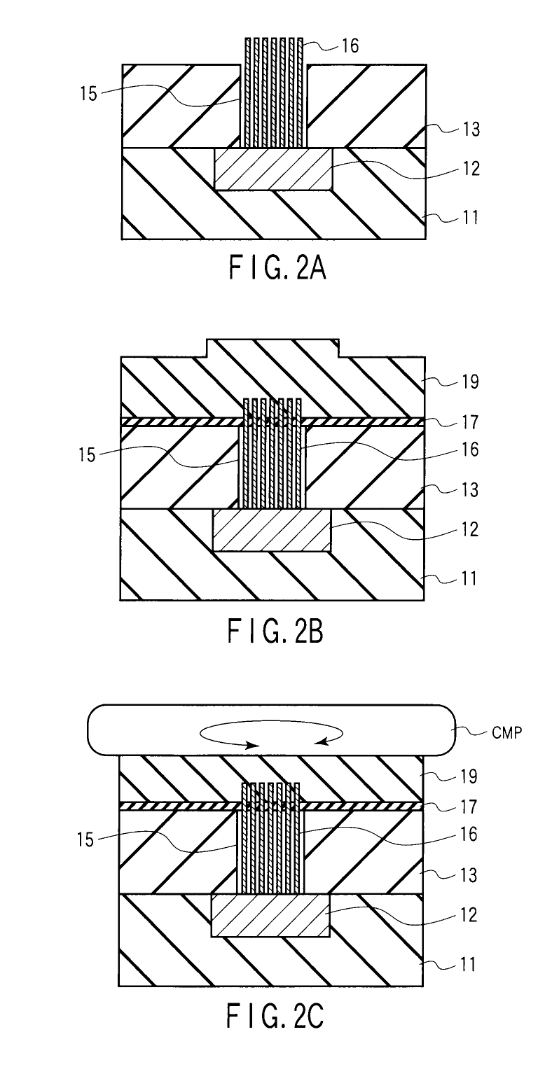

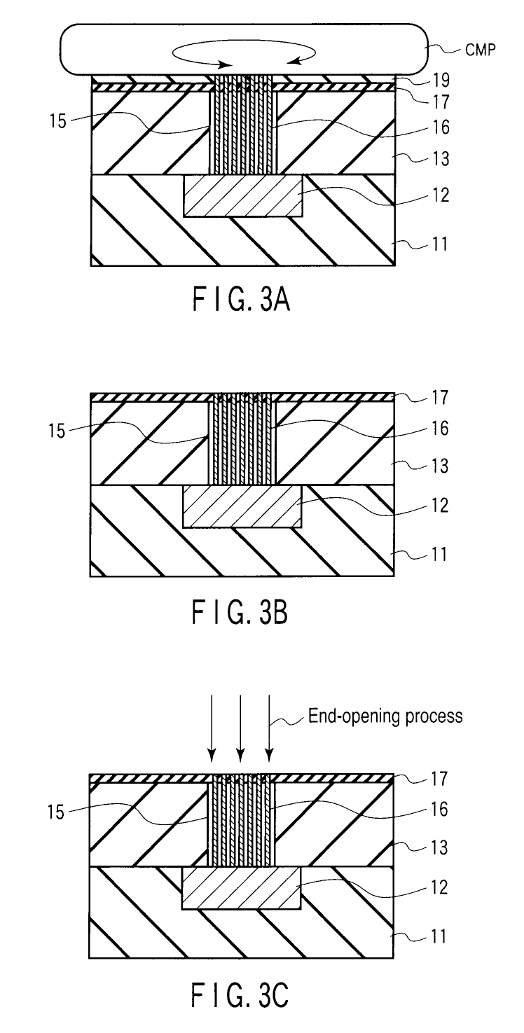

FIGS. 2A to 3C are sectional views showing a method of manufacturing the carbon nanotube plug interconnect of the first embodiment.

After an interconnect trench is formed in an interlayer dielectric film 11, a first interconnection layer 12 is formed in the interconnect trench, as shown in FIG. 2A. After that, an interlayer dielectric film 13 is formed on the interlayer dielectric film 11 and first interconnection layer 12 by, e.g., chemical vapor deposition (CVD). In addition, a contact hole 15 is formed in the interlayer dielectric film 13 on the first interconnection layer 12 by lithography.

Subsequently, carbon nanotubes 16 are formed on the first interconnection layer 12 in the contact hole 15. More specifically, the carbon nanotubes 16 are grown in the contact hole 15 from the surface of the first interconnection layer 12 by the ordinary method, until they protrude from the contact hole 15. That is, the carbon nanotubes 16 having ends protruding from the contact hole 15 are formed.

Then, as shown in FIG. 2B, a stopper film 17 is formed by CVD on the interlayer dielectric film 13 and between the carbon nanotubes 16 above the contact hole 15. In this step, the stopper film 17 enters and fills the spaces between the carbon nanotubes 16 above the contact hole 15 and near the opening of the contact hole 15. Thus, the stopper film 17 fixes the carbon nanotubes 16.

After that, an interlayer dielectric film is formed on the stopper film 17 and carbon nanotubes 16. For example, a spin-on-glass (SOG) film 19 is formed by spin coating.

As shown in FIG. 2C, the SOG film 19 and carbon nanotubes 16 above the stopper film 17 are polished by CMP. More specifically, the SOG film 19 above the carbon nanotubes 16 is polished first. When the polished portion has reached the carbon nanotubes 16 after that, the carbon nanotubes 16 are polished together with the SOG film 19, as shown in FIG. 3A. Then, as shown in FIG. 3B, the SOG film 19 on the stopper film 17 is polished, and the carbon nanotubes 16 protruding upward from the stopper film 17 over the contact hole 15 are polished.

Note that the stopper film 17 is made of an insulating film, e.g., SiN, SiC, or SiCN having selectivity to the SOG film 19 in the CMP step of polishing the SOG film 19 and carbon nanotubes 16. In other words, a film whose polishing rate in the CMP step is lower than that of the SOG film 19 is used as the stopper film 17. This facilitates stopping the polishing when the SOG film 19 and carbon nanotubes 16 above the stopper film 17 are polished.

In this step, the carbon nanotubes 16 are fixed by the stopper film 17 filled between them. In the polishing step (CMP step), therefore, it is possible to suppress a lateral force acting on the carbon nanotubes 16, thereby preventing damage to the carbon nanotubes 16. That is, it is possible to prevent the carbon nanotubes 16 from falling or being pulled out from the contact hole 15, and form carbon nanotubes 16 having aligned upper surfaces. This makes it possible to reduce pattern defects of the carbon nanotubes 16 and electrical characteristic defects caused by dust.

After that, as shown in FIG. 3C, an end-opening process is performed on the exposed ends of the carbon nanotubes 16. Examples of this end-opening process are a method of destroying the ends of the carbon nanotubes by irradiation with an energy line such as a plasma, UV light, or an ion beam, and a method of processing the ends of the carbon nanotubes by a reaction with a chemical species or radical such as oxygen, hydrogen, or fluorine.

Subsequently, a barrier metal 18 is formed on the end-opened carbon nanotubes 16 and stopper film 17 by, e.g., sputtering, CVD, or atomic layer deposition (ALD). In addition, an aluminum film serving as a second interconnection layer 14 is formed on the barrier metal 18. The second interconnection layer 14 is formed by patterning the barrier metal 18 and aluminum film by lithography, as shown in FIG. 1A.

When the dielectric constant of the stopper film is high, it is favorable to entirely remove the stopper film from the viewpoint of the dielectric constant. If there is no film fixing the upper ends of the carbon nanotubes, however, the sidewalls of the carbon nanotubes are damaged when performing the end-opening process or the like.

As described previously, therefore, a double structure such as a multilayered film of SiN and SiO₂ or a multilayered film of SiN and SiOC can also be used as the stopper film 17. SiN is a high-k film, and SiO₂ or SiOC is a low-k film. When using the double structure as described above such that the upper layer (SiN) is removed after the CMP step and the lower layer (SiO₂ or SiOC) is left behind, it is possible to remove the high-k film and leave the film that fixes the upper ends of the carbon nanotubes behind.

Even when the stopper film is a single layer, the stopper film 17 can be deposited to enter the spaces between the carbon nanotubes 16 in the contact hole 15, as shown in FIG. 1B. In this case, even after the single-layered stopper film 17 is removed, the opening of the contact hole 15 can be closed with the stopper film. This makes it possible to prevent damage to the sidewalls of the carbon nanotubes when performing the end-opening process or the like.

### [1-3] Effects of First Embodiment

In the first embodiment, the carbon nanotubes 16 are fixed by the stopper film 17 filled between them. Therefore, damage to the carbon nanotubes 16 can be prevented in the step of polishing the carbon nanotubes 16 protruding from the contact hole 15. This makes it possible to reduce pattern defects of the carbon nanotubes 16 and electrical characteristic defects caused by dust, thereby improving the electrical connection between the first interconnection layer 12 and second interconnection layer 14.

Furthermore, in the end-opening process of the carbon nanotubes 16, the opening of the contact hole 15 is blocked with the stopper film 17. During the end-opening process, therefore, the amount of energy line, chemical species, or radical entering the contact hole can be reduced. This makes it possible to prevent damage to the sidewalls of the carbon nanotubes 16 in the contact hole 15 and to the surface of the first interconnection layer 12 on the bottom of the contact hole.

### [2] Second Embodiment

In the second embodiment, an example in which a metal film or the like as a stopper film is formed on an interlayer dielectric film having a plug interconnect and a second interconnection layer is formed in an etching step will be explained. In a CMP step of polishing carbon nanotubes protruding from a contact hole, the metal film or the like on the interlayer dielectric film functions as a stopper film and fixes the carbon nanotubes.

### [2-1] Carbon Nanotube Plug Interconnect

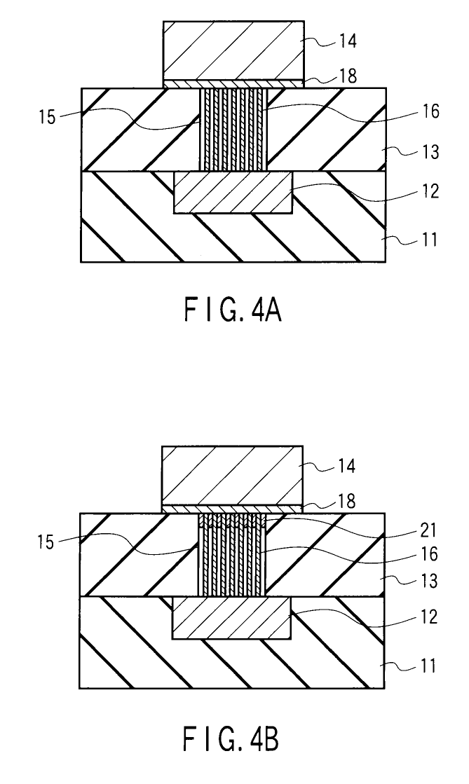

FIG. 4A is a sectional view showing a carbon nanotube plug interconnect of the second embodiment.

As shown in FIG. 4A, a first interconnection layer 12 is formed in an interlayer dielectric film 11. The interlayer dielectric film 11 is formed on a semiconductor substrate (not shown). The first interconnection layer 12 is buried in the interlayer dielectric film 11 so as to expose the surface. A barrier metal (not shown) is formed between the first interconnection layer 12 and the interlayer dielectric film 11 as needed.

An interlayer dielectric film 13 is formed on the interlayer dielectric film 11 and first interconnection layer 12. In the interlayer dielectric film 13 on the first interconnection layer 12, a contact hole 15 for electrically connecting a second interconnection layer 14 and the first interconnection layer 12 is formed. Carbon nanotubes 16 are formed in the contact hole 15. The carbon nanotubes 16 electrically connect the first interconnection layer 12 and second interconnection layer 14.

A barrier metal 18 is formed on the carbon nanotubes 16 and the interlayer dielectric film 13. The second interconnection layer 14 is formed on the barrier metal 18. The carbon nanotubes 16 each have one end in contact with the first interconnection layer 12, and the other end in contact with the barrier metal 18. The first interconnection layer 12 and second interconnection layer 14 are electrically connected via the carbon nanotubes 16.

Note that FIG. 4A shows an example in which the metal film as a stopper film does not remain at the ends of the carbon nanotubes 16 on the side of the second interconnection layer 14. However, as shown in FIG. 4B, a stopper film 21 can also be formed at the ends of the carbon nanotubes 16 on the side of the second interconnection layer 14. That is, the stopper film 21 may enter the contact hole from the bottom surface of the barrier metal 18. The stopper film 21 is made of a metal film, metal compound, refractory metal, or refractory metal compound, e.g., Ta, TaN, TiN, or W. The stopper film 21 can also be made of amorphous silicon.

### [2-2] Method of Manufacturing Carbon Nanotube Plug Interconnect

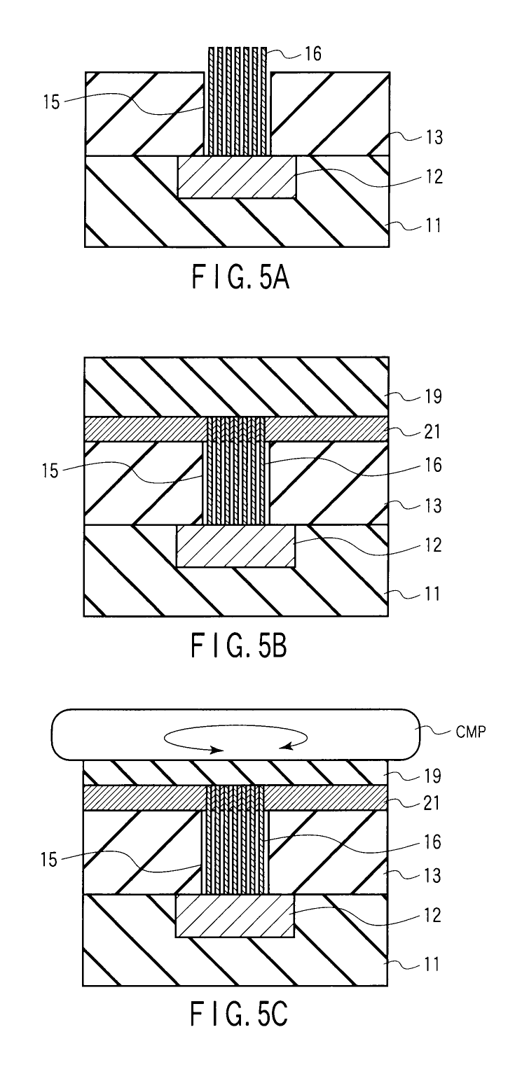

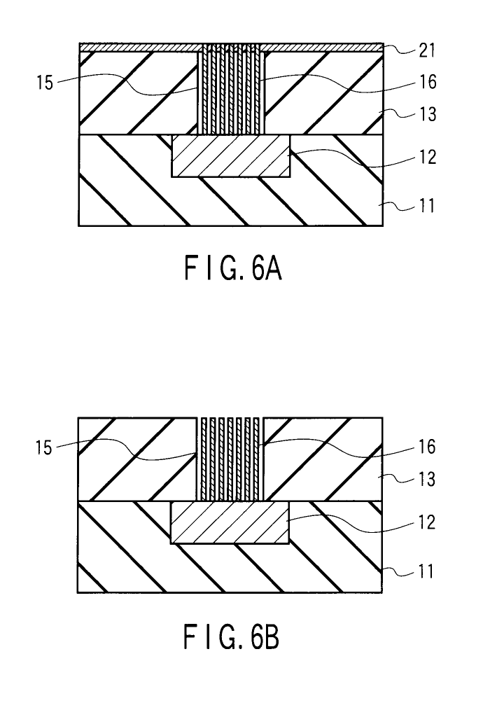

FIGS. 5A to 6B are sectional views showing a method of manufacturing the carbon nanotube plug interconnect of the second embodiment.

After an interconnect trench is formed in an interlayer dielectric film 11, a first interconnection layer 12 is formed in the interconnect trench, as shown in FIG. 5A. After that, an interlayer dielectric film 13 is formed on the interlayer dielectric film 11 and first interconnection layer 12 by, e.g., CVD. In addition, a contact hole 15 is formed in the interlayer dielectric film 13 on the first interconnection layer 12 by lithography.

Subsequently, carbon nanotubes 16 are formed on the first interconnection layer 12 in the contact hole 15. More specifically, the carbon nanotubes 16 are grown from the surface of the first interconnection layer 12 by the ordinary method until they protrude from the contact hole 15.

Then, as shown in FIG. 5B, a stopper film 21, e.g., a metal film is formed by sputtering on the interlayer dielectric film 13 and between the carbon nanotubes 16 above the contact hole 15. In this step, the stopper film 21 enters and fills the spaces between the carbon nanotubes 16 above the contact hole 15 and near the opening of the contact hole 15. Thus, the stopper film 21 fixes the carbon nanotubes 16. After that, an SOG film 19 is formed on the stopper film 21 and carbon nanotubes 16 by spin coating.

As shown in FIGS. 5C and 6A, the SOG film 19, stopper film 21, and carbon nanotubes 16 are polished by CMP. More specifically, the SOG film 19 on the carbon nanotubes 16 and stopper film 21 is polished first. When the polished portion has reached the carbon nanotubes 16 after that, the carbon nanotubes 16 are polished together with the stopper film 21. As shown in FIG. 6B, the polishing of the stopper film 21 and carbon nanotubes 16 is further advanced, thereby removing the SOG film 19 and carbon nanotubes 16 on the interlayer dielectric film 13 and above the contact hole 15.

In this step, since the carbon nanotubes 16 are fixed by the stopper film 21 filled between them, they are intensively polished at the stopper film 21. In the polishing step (CMP step), therefore, it is possible to suppress a lateral force acting on the carbon nanotubes 16, thereby preventing damage to the carbon nanotubes 16. That is, it is possible to prevent the carbon nanotubes 16 from falling or being pulled out from the contact hole 15. This makes it possible to reduce pattern defects of the carbon nanotubes 16 and electrical characteristic defects caused by dust.

After that, an end-opening process is performed on the exposed ends of the carbon nanotubes 16 above the contact hole. This end-opening process is preferably performed immediately before the next sputtering step, and can also be performed as pre-processing of the sputtering step.

Subsequently, a barrier metal 18 is formed on the carbon nanotubes 16 and the interlayer dielectric film 13 by, e.g., sputtering. In addition, an aluminum film serving as a second interconnection layer 14 is formed on the barrier metal 18. The second interconnection layer 14 is formed by patterning the barrier metal 18 and aluminum film by lithography, as shown in FIG. 4A.

Note that if there is no film fixing the upper ends of the carbon nanotubes, the sidewalls of the carbon nanotubes are damaged when performing the end-opening process or the like. Therefore, the double structure of a multilayered film including a metal film or the like and an insulating film can also be used. When using the double structure as described above such that the upper layer (metal film or the like) is removed after the CMP step and the lower layer (insulating film) is left behind, it is possible to prevent damage to the sidewalls of the carbon nanotubes when performing the end-opening process or the like. Note that the rest of the arrangement such as the materials to be used are the same as those of the first embodiment.

### [2-3] Effects of Second Embodiment

In the second embodiment as has been explained above, the carbon nanotubes 16 are fixed by the stopper film 21 filled between them. Therefore, damage to the carbon nanotubes 16 can be prevented in the step of polishing the carbon nanotubes 16 protruding from the contact hole 15. This makes it possible to reduce pattern defects of the carbon nanotubes 16 and electrical characteristic defects caused by dust, thereby improving the electrical connection between the first interconnection layer 12 and second interconnection layer 14.

### [2-4] Carbon Nanotube Plug Interconnect and Method of Manufacturing the Same of Modification

In this modification, a metal film or the like as a stopper film 21 is not entirely removed but left behind in a CMP step of polishing carbon nanotubes 16 protruding from a contact hole 15.

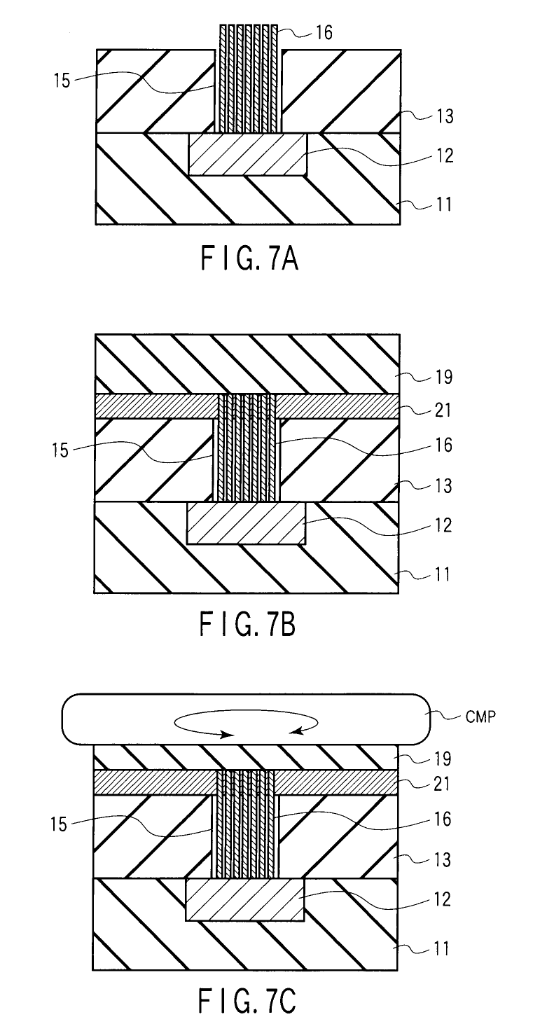

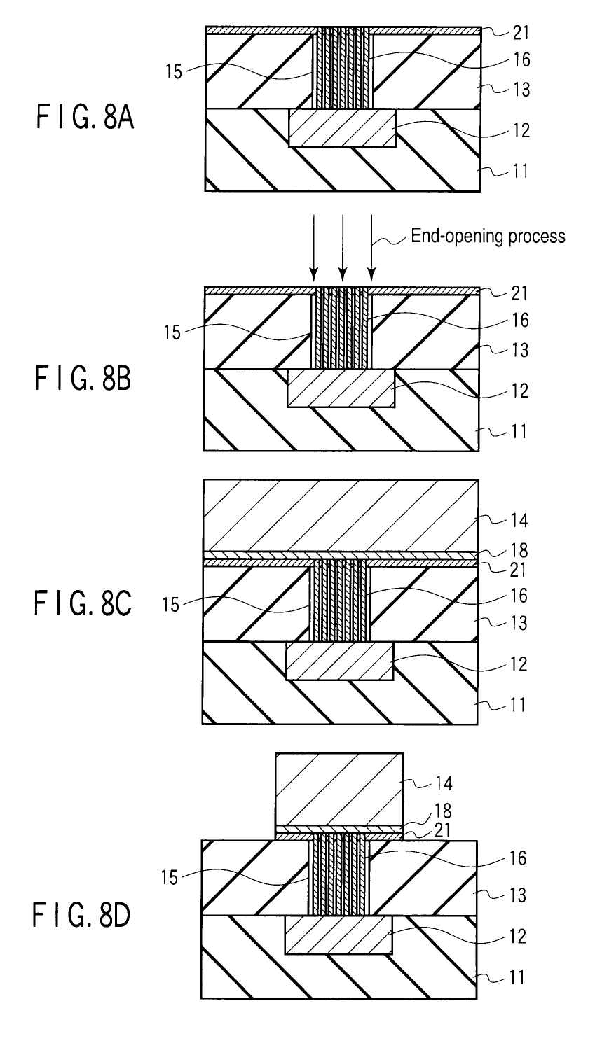

Steps shown in FIGS. 7A to 8A are the same as those shown in FIGS. 5A to 6A described previously, so a repetitive explanation will be omitted.

As shown in FIG. 8A, the stopper film 21 and carbon nanotubes 16 are polished and left behind by a predetermined thickness on an interlayer dielectric film 13 and over a contact hole 15.

Then, as shown in FIG. 8B, an end-opening process is performed on the exposed ends of the carbon nanotubes 16. This end-opening process is preferably performed immediately before the next sputtering step, and can also be performed as pre-processing of the sputtering step.

Subsequently, as shown in FIG. 8C, a barrier metal 18 is formed on the end-opened carbon nanotubes 16 and stopper film 21 by, e.g., sputtering. In addition, an aluminum film serving as a second interconnection layer 14 is formed on the barrier metal 18. The second interconnection layer 14 is formed by patterning the barrier metal 18, aluminum film, and stopper film 21 by lithography, as shown in FIG. 8D.

### [2-5] Effects of Modification of Second Embodiment

In the modification of the second embodiment, as in the second embodiment, damage to the carbon nanotubes 16 can be prevented in the step of polishing the carbon nanotubes 16, because the carbon nanotubes 16 are fixed by the stopper film 21.

In addition, during the end-opening process of the carbon nanotubes 16, it is possible to reduce the amount of energy line, chemical species, or radical entering the contact hole 15, because the opening of the contact hole 15 is blocked with the stopper film 21. This makes it possible to prevent damage to the sidewalls of the carbon nanotubes 16 in the contact hole 15 and to the surface of a first interconnection layer 12 on the bottom of the contact hole.

### [3] Third Embodiment

In the third embodiment, an example in which an insulating film as a stopper film is formed on an interlayer dielectric film having a plug interconnect and a second interconnection layer is formed by the single damascene method will be explained. In a CMP step of polishing carbon nanotubes protruding from a contact hole, the insulating film on the interlayer dielectric film functions as a stopper film and fixes the carbon nanotubes.

### [3-1] Carbon Nanotube Plug Interconnect

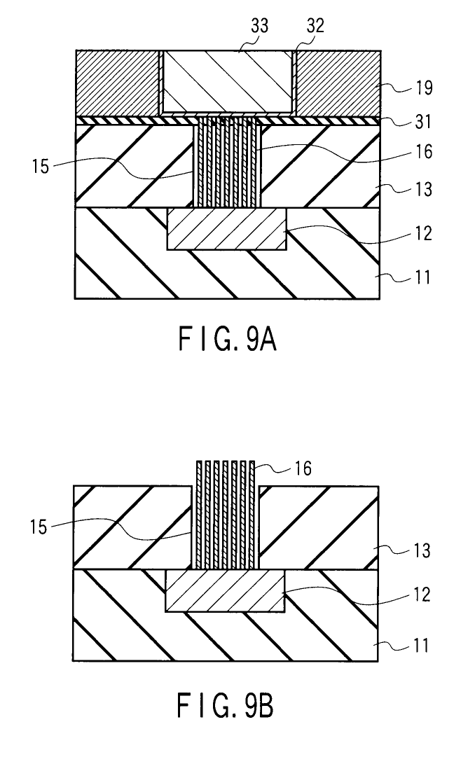

FIG. 9A is a sectional view showing a carbon nanotube plug interconnect of the third embodiment.

As shown in FIG. 9A, a first interconnection layer 12 is formed in an interlayer dielectric film 11. The interlayer dielectric film 11 is formed on a semiconductor substrate (not shown). The first interconnection layer 12 is buried in the interlayer dielectric film 11 so as to expose the surface. A barrier metal (not shown) is formed between the first interconnection layer 12 and the interlayer dielectric film 11 as needed.

An interlayer dielectric film 13 is formed on the interlayer dielectric film 11 and first interconnection layer 12. In the interlayer dielectric film 13 on the first interconnection layer 12, a contact hole 15 for electrically connecting a second interconnection layer 33 and the first interconnection layer 12 is formed. Carbon nanotubes 16 are formed in the contact hole 15. The carbon nanotubes 16 electrically connect the first interconnection layer 12 and second interconnection layer 33. The second interconnection layer 33 is made of, e.g., Cu.

A stopper film 31 is formed on the interlayer dielectric film 13. The stopper film 31 is filled in the ends of the carbon nanotubes 16 on the side of the second interconnection layer 33 so as to fix the carbon nanotubes 16. The stopper film 31 is made of an insulating film, e.g., SiN or SiO₂.

An interlayer dielectric film, e.g., an SOG film 19 is formed on the stopper film 31. An interconnect trench is formed in the SOG film 19 over the contact hole 15. A barrier metal 32 is formed in this interconnect trench, and the second interconnection layer 33 is formed on the barrier metal 32. The carbon nanotubes 16 each have one end in contact with the first interconnection layer 12, and the other end in contact with the barrier metal 32. The first interconnection layer 12 and second interconnection layer 33 are electrically connected via the carbon nanotubes 16. The barrier metal 32 is made of at least one of, e.g., Ta, TaN, Ti, and TiN, or a multilayered film of these metals. The second interconnection layer 33 is made of, e.g., Cu.

Note that FIG. 9A shows an example in which the stopper film 31 is formed at the ends of the carbon nanotubes 16 on the side of the second interconnection layer 33, from the bottom surface of the barrier metal 32 to that of the stopper film 31. However, the stopper film 31 can also be formed from the bottom surface of the barrier metal 32 to a position deeper than the bottom surface of the stopper film 31. That is, the stopper film 31 may enter the contact hole from the bottom surface of the barrier metal 32.

### [3-2] Method of Manufacturing Carbon Nanotube Plug Interconnect

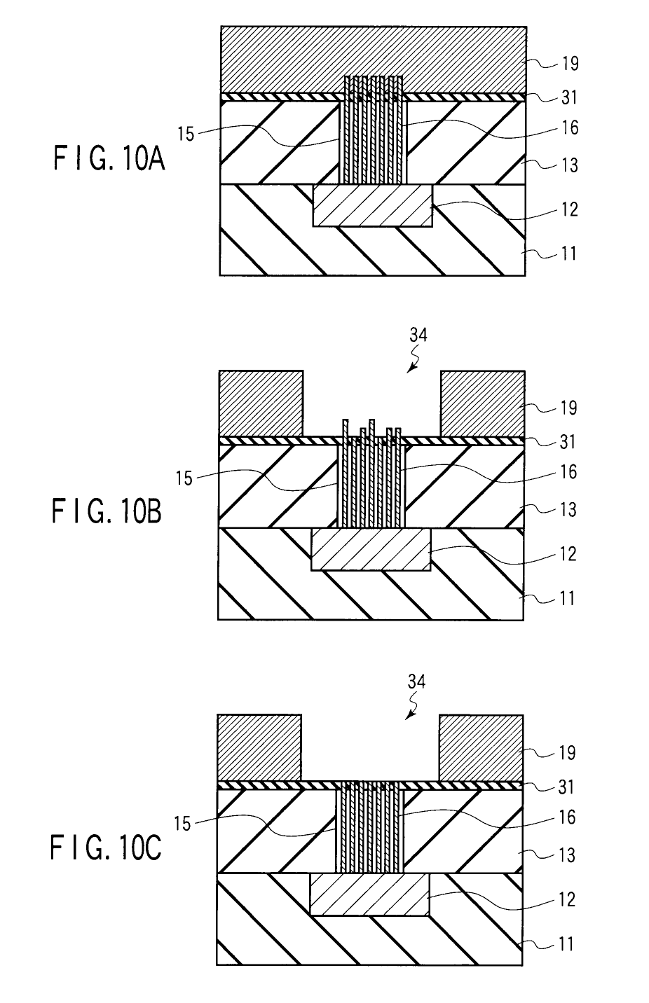

FIGS. 9B to 10C are sectional views showing a method of manufacturing the carbon nanotube plug interconnect of the third embodiment.

After an interconnect trench is formed in an interlayer dielectric film 11, a first interconnection layer 12 is formed in the interconnect trench, as shown in FIG. 9B. After that, an interlayer dielectric film 13 is formed on the interlayer dielectric film 11 and first interconnection layer 12 by, e.g., CVD. In addition, a contact hole 15 is formed in the interlayer dielectric film 13 on the first interconnection layer 12 by lithography.

Subsequently, carbon nanotubes 16 are formed on the first interconnection layer 12 in the contact hole 15. More specifically, the carbon nanotubes 16 are grown from the surface of the first interconnection layer 12 by the ordinary method until they protrude from the contact hole 15.

Then, as shown in FIG. 10A, a stopper film 31 is formed by CVD on the interlayer dielectric film 13 and between the carbon nanotubes 16 above the contact hole 15. In this step, the stopper film 31 enters and fills the spaces between the carbon nanotubes 16 above the contact hole 15 and near the opening of the contact hole 15. Thus, the stopper film 31 fixes the carbon nanotubes 16.

After that, an interlayer dielectric film is formed on the stopper film 31 and carbon nanotubes 16. For example, an SOG film 19 is formed by spin coating. As the stopper film 31, a film having etching selectivity much higher than that of the SOG film 19 is used.

As shown in FIG. 10B, an interconnect trench 34 is formed in the SOG film 19 over the contact hole 15 by reactive ion etching (RIE) using lithography. Subsequently, as shown in FIG. 10C, plasma processing, e.g., RIE is performed on the carbon nanotubes 16 protruding from the stopper film 31 in the interconnect trench 34, thereby removing the carbon nanotubes 16 protruding from the stopper film 31, and performing an end-opening process of opening the ends of the carbon nanotubes 16. This end-opening process is preferably performed immediately before the next sputtering step, and can also be performed as pre-processing of the sputtering step.

Since the stopper film 31 is filled between the carbon nanotubes 16 above the contact hole 15, it is possible to reduce the amount of energy line, chemical species, or radical entering the contact hole in the above-mentioned plasma processing. This makes it possible to prevent damage to the sidewalls of the carbon nanotubes 16 in the contact hole 15 and to the surface of the first interconnection layer 12 on the bottom of the contact hole.

Then, a barrier metal is formed in the interconnect trench 34 by, e.g., sputtering, and a Cu film is formed on the barrier metal. The Cu film and barrier metal on the SOG film 19 are polished by CMP, thereby forming a barrier metal 32 and second interconnection layer 33 in the interconnect trench 34, as shown in FIG. 9A.

### [3-3] Effects of Third Embodiment

In the third embodiment as has been explained above, the stopper film 31 is filled between the carbon nanotubes 16 above the contact hole 15. Therefore, the amount of energy line, chemical species, or radical entering the contact hole can be reduced during the etching process and end-opening process of the carbon nanotubes 16. This makes it possible to prevent damage to the sidewalls of the carbon nanotubes 16 in the contact hole 15 and to the surface of the first interconnection layer 12 on the bottom of the contact hole. Consequently, it is possible to prevent electrical defects of the plug interconnect having the carbon nanotubes 16, thereby improving the electrical connection between the first interconnection layer 12 and second interconnection layer 33.

### [3-4] Method of Manufacturing Carbon Nanotube Plug Interconnect of Modification

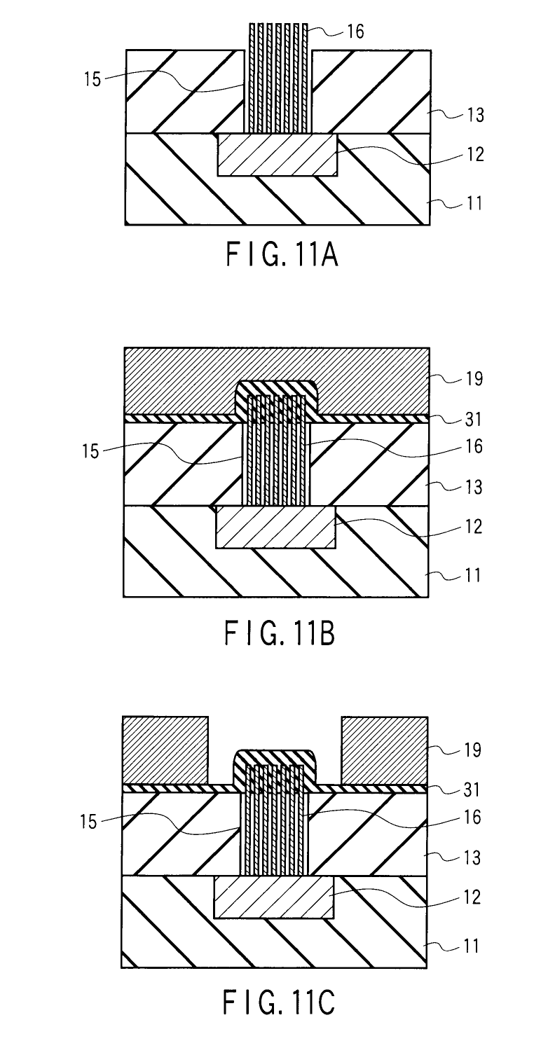

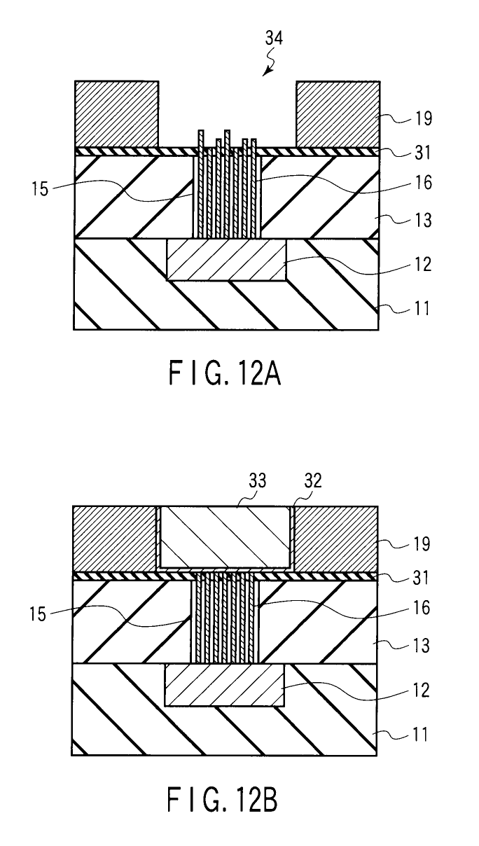

FIGS. 11A to 12B are sectional views showing a method of manufacturing a carbon nanotube plug interconnect of a modification of the third embodiment.

In this modification, when a stopper film 31 is formed on an interlayer dielectric film 13 and over a contact hole 15 by CVD, as shown in FIG. 11B, the stopper film 31 enters the spaces between carbon nanotubes 16, and is formed on the carbon nanotubes 16.

A step shown in FIG. 11A is the same as that shown in FIG. 9B described previously, so a repetitive explanation will be omitted. After that, as shown in FIG. 11B, the stopper film 31 is formed by CVD on the interlayer dielectric film 13, and formed on and between the carbon nanotubes 16 above the contact hole 15. In this step, the stopper film 31 is formed on the carbon nanotubes 16 under predetermined deposition conditions, and enters and fills the spaces between the carbon nanotubes 16 above the contact hole 15 and near the opening of the contact hole 15. Thus, the stopper film 31 fixes the carbon nanotubes 16.

After that, interlayer dielectric film is formed on the stopper film 31 and carbon nanotubes 16. For example, an SOG film 19 is formed by spin coating.

Then, as shown in FIG. 11C, an interconnect trench 34 is formed in the SOG film 19 over the contact hole 15 by lithography. Subsequently, as shown in FIG. 12A, the stopper film 31 on the carbon nanotubes 16 in the interconnect trench 34 is etched by, e.g., RIE. In addition, plasma processing, e.g., RIE is performed on the carbon nanotubes 16 protruding from the stopper film 31, thereby removing the carbon nanotubes 16 protruding from the stopper film 31, and performing an end-opening process of opening the ends of the carbon nanotubes 16. This end-opening process is preferably performed immediately before the next sputtering step, and can also be performed as pre-processing of the sputtering step.

Since the stopper film 31 is filled between the carbon nanotubes 16 above the contact hole 15, it is possible, in the above-mentioned plasma processing, to prevent damage to the sidewalls of the carbon nanotubes 16 in the contact hole 15 and to the surface of the first interconnection layer 12 on the bottom of the contact hole.

Then, a barrier metal is formed in the interconnect trench 34 by, e.g., sputtering, and a Cu film is formed on the barrier metal. The Cu film and barrier metal on the SOG film 19 are polished by CMP, thereby forming a barrier metal 32 and second interconnection layer 33 in the interconnect trench 34, as shown in FIG. 12B. The rest of the arrangement and effects are the same as those of the third embodiment described above.

### [4] Fourth Embodiment

In the fourth embodiment, an example in which a metal film or the like as a stopper film is formed on an interlayer dielectric film having a plug interconnect and a second interconnection layer is formed by the single damascene method will be explained. In a CMP step of polishing carbon nanotubes protruding from a contact hole, the metal film or the like on the interlayer dielectric film functions as a stopper film and fixes the carbon nanotubes.

### [4-1] Carbon Nanotube Plug Interconnect

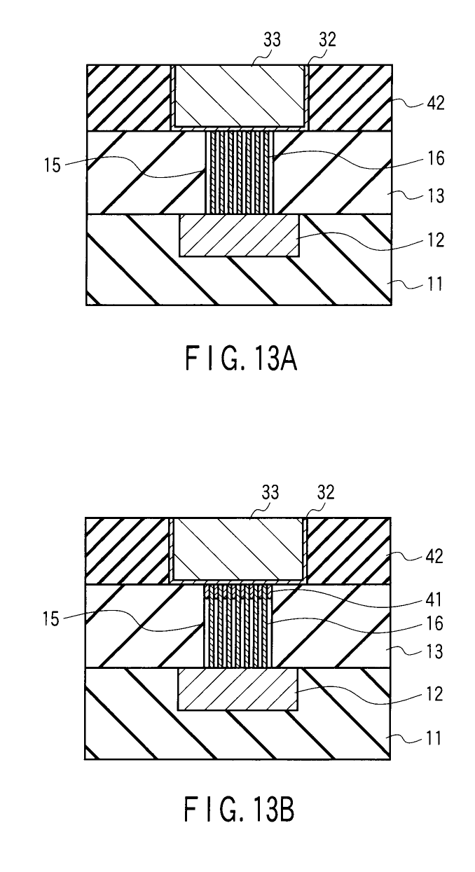

FIG. 13A is a sectional view showing a carbon nanotube plug interconnect of the fourth embodiment.

As shown in FIG. 13A, a first interconnection layer 12 is formed in an interlayer dielectric film 11. The interlayer dielectric film 11 is formed on a semiconductor substrate (not shown). The first interconnection layer 12 is buried in the interlayer dielectric film 11 so as to expose the surface. A barrier metal (not shown) is formed between the first interconnection layer 12 and the interlayer dielectric film 11 as needed.

An interlayer dielectric film 13 is formed on the interlayer dielectric film 11 and first interconnection layer 12. In the interlayer dielectric film 13 on the first interconnection layer 12, a contact hole 15 for electrically connecting a second interconnection layer 33 and the first interconnection layer 12 is formed. Carbon nanotubes 16 are formed in the contact hole 15. The carbon nanotubes 16 electrically connect the first interconnection layer 12 and second interconnection layer 33. The second interconnection layer 33 is made of, e.g., Cu.

An interlayer dielectric film, e.g., an SOG film 42 is formed on the interlayer dielectric film 13. An interconnect trench is formed in the SOG film 42 over the contact hole 15. A barrier metal 32 is formed in this interconnect trench, and the second interconnection layer 33 is formed on the barrier metal 32. The carbon nanotubes 16 each have one end in contact with the first interconnection layer 12, and the other end in contact with the barrier metal 32. The first interconnection layer 12 and second interconnection layer 33 are electrically connected via the carbon nanotubes 16.

Note that FIG. 13A shows an example in which the metal film as a stopper film does not remain at the ends of the carbon nanotubes 16 on the side of the second interconnection layer 33. As shown in FIG. 13B, however, a stopper film 41 can also be formed at the ends of the carbon nanotubes 16 on the side of the second interconnection layer 33. That is, the stopper film 41 may enter the contact hole from the bottom surface of the barrier metal 32. The stopper film 41 is made of a metal film, metal compound, refractory metal, or refractory metal compound, e.g., Ta, TaN, TiN, or W. The stopper film 41 can also be made of amorphous silicon.

### [4-2] Method of Manufacturing Carbon Nanotube Plug Interconnect

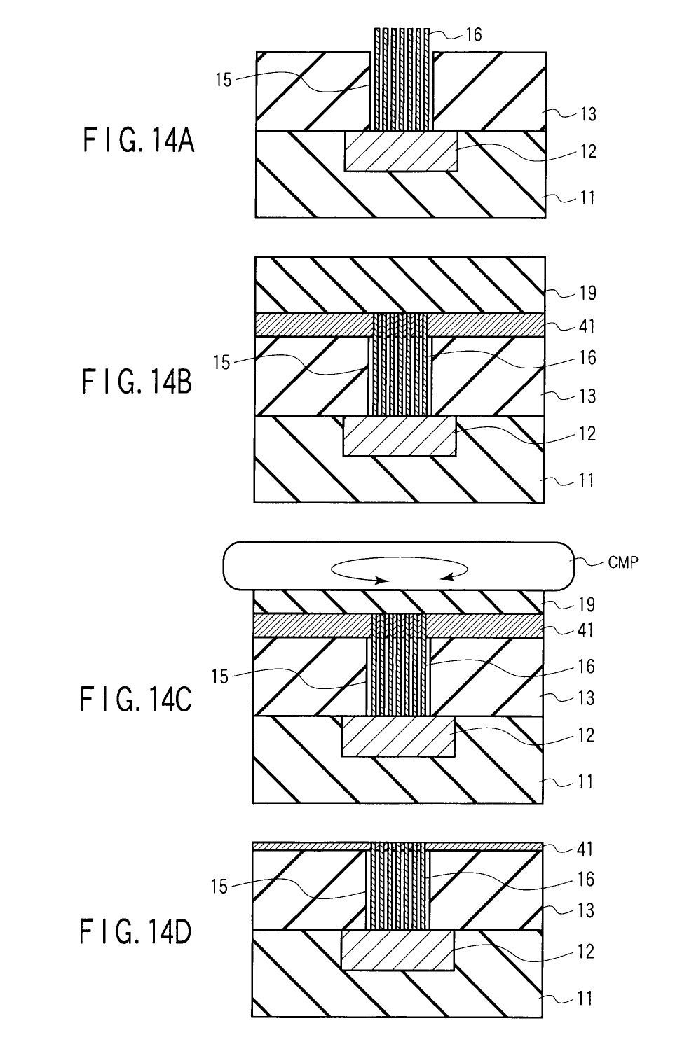

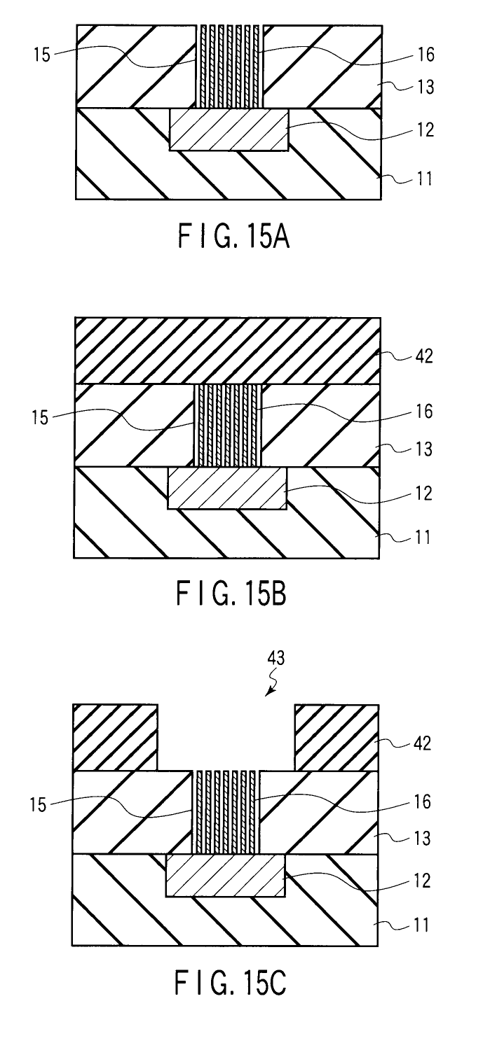

FIGS. 14A to 15C are sectional views showing a method of manufacturing the carbon nanotube plug interconnect of the fourth embodiment.

After an interconnect trench is formed in an interlayer dielectric film 11, a first interconnection layer 12 is formed in the interconnect trench, as shown in FIG. 14A. After that, an interlayer dielectric film 13 is formed on the interlayer dielectric film 11 and first interconnection layer 12 by, e.g., CVD. In addition, a contact hole 15 is formed in the interlayer dielectric film 13 on the first interconnection layer 12 by lithography.

Subsequently, carbon nanotubes 16 are formed on the first interconnection layer 12 in the contact hole 15. More specifically, the carbon nanotubes 16 are grown from the surface of the first interconnection layer 12 by the ordinary method until they protrude from the contact hole 15.

Then, as shown in FIG. 14B, a stopper film 41, e.g., a metal film is formed by sputtering on the interlayer dielectric film 13 and between the carbon nanotubes 16 above the contact hole 15. In this step, the stopper film 41 enters and fills the spaces between the carbon nanotubes 16 above the contact hole 15 and near the opening of the contact hole 15. Thus, the stopper film 41 fixes the carbon nanotubes 16. After that, an SOG film 19 is formed on the stopper film 41 and carbon nanotubes 16 by spin coating.

As shown in FIGS. 14C and 14D, the SOG film 19, stopper film 41, and carbon nanotubes 16 are polished by CMP. More specifically, the SOG film 19 on the carbon nanotubes 16 and stopper film 41 is polished first. When the polished portion has reached the carbon nanotubes 16 after that, the carbon nanotubes 16 are polished together with the stopper film 41. As shown in FIG. 15A, the polishing of the stopper film 41 and carbon nanotubes 16 is further advanced, thereby removing the stopper film 41 and carbon nanotubes 16 on the interlayer dielectric film 13 and above the contact hole 15.

In this step, the carbon nanotubes 16 are fixed by the stopper film 41 filled between them. In the above-described polishing step (CMP step), therefore, it is possible to suppress a lateral force acting on the carbon nanotubes 16, thereby preventing damage to the carbon nanotubes 16. That is, it is possible to prevent the carbon nanotubes 16 from falling or being pulled out from the contact hole 15. This makes it possible to reduce pattern defects of the carbon nanotubes 16 and electrical characteristic defects caused by dust.

After that, as shown in FIG. 15B, an SOG film 42 is formed on the interlayer dielectric film 13 and over the contact hole 15. In addition, as shown in FIG. 15C, an interconnect trench 43 is formed in the SOG film 42 over the contact hole 15 by RIE using lithography. Subsequently, an end-opening process is performed on the exposed ends of the carbon nanotubes 16 in the interconnect trench 43 as needed. This end-opening process is preferably performed immediately before the next sputtering step, and can also be performed as pre-processing of the sputtering step.

Then, a barrier metal is formed in the interconnect trench 43 by, e.g., sputtering, and a Cu film is formed on the barrier metal. The Cu film and barrier metal on the SOG film 42 are polished by CMP, thereby forming a barrier metal 32 and second interconnection layer 33 in the interconnect trench 43, as shown in FIG. 13A.

### [4-3] Effects of Fourth Embodiment

In the fourth embodiment as has been explained above, the carbon nanotubes 16 are fixed by the stopper film 41 filled between them. Therefore, damage to the carbon nanotubes 16 can be prevented in the step of polishing the carbon nanotubes 16 protruding from the contact hole 15. This makes it possible to reduce pattern defects of the carbon nanotubes 16 and electrical characteristic defects caused by dust, thereby improving the electrical connection between the first interconnection layer 12 and second interconnection layer 33.

### [5] Fifth Embodiment

In the fifth embodiment, an example in which an insulating film is formed over a contact hole as a protective film to be used when etching carbon nanotubes protruding from the contact hole and a second interconnection layer is formed by the dual damascene method will be explained.

### [5-1] Carbon Nanotube Plug Interconnect

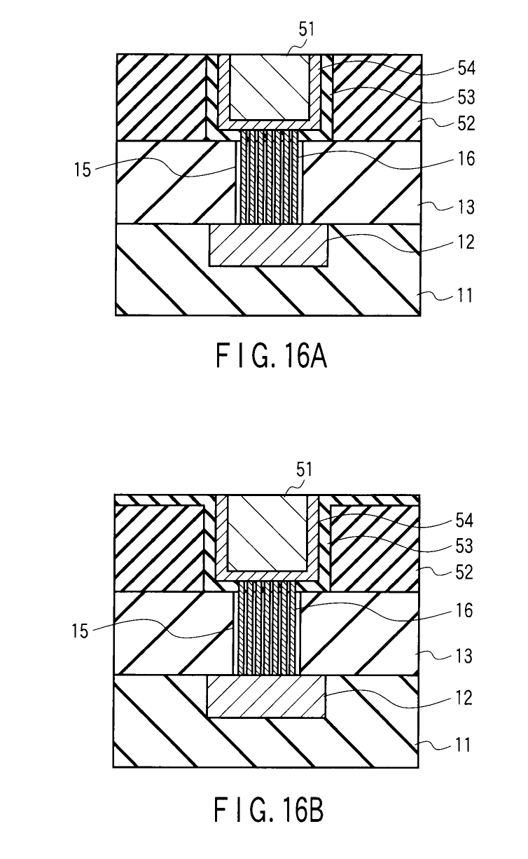

FIG. 16A is a sectional view showing a carbon nanotube plug interconnect of the fifth embodiment.

As shown in FIG. 16A, a first interconnection layer 12 is formed in an interlayer dielectric film 11. The interlayer dielectric film 11 is formed on a semiconductor substrate (not shown). The first interconnection layer 12 is buried in the interlayer dielectric film 11 so as to expose the surface. A barrier metal (not shown) is formed between the first interconnection layer 12 and the interlayer dielectric film 11 as needed.

An interlayer dielectric film 13 is formed on the interlayer dielectric film 11 and first interconnection layer 12. In the interlayer dielectric film 13 on the first interconnection layer 12, a contact hole 15 for electrically connecting a second interconnection layer 51 and the first interconnection layer 12 is formed. Carbon nanotubes 16 are formed in the contact hole 15. The carbon nanotubes 16 electrically connect the first interconnection layer 12 and second interconnection layer 51. The second interconnection layer 51 is made of, e.g., Cu.

An interlayer dielectric film 52, e.g., SiO₂ is formed on the interlayer dielectric film 13. An interconnect trench is formed in the interlayer dielectric film 52 over the contact hole 15. A protective film 53 is formed in this interconnect trench so as to cover it. The protective film 53 is filled between the carbon nanotubes 16 protruding from the contact hole 15. The protective film 53 is made of an insulating film, e.g., SiO₂, SiN, or SiCN.

A barrier metal 54 is formed on the protective film 53 in the interconnect trench so as to cover the protective film 53. In addition, the second interconnection layer 51 is formed on the barrier metal 54 in the interconnect trench. The barrier metal 54 is positioned between the second interconnection layer 51 and protective film 53, and prevents the diffusion of the material of the second interconnection layer 51 to the protective film 53 and the interlayer dielectric film 52.

Note that FIG. 16A shows an example in which the protective film 53 is not formed on the interlayer dielectric film 52, i.e., the protective film 53 does not remain on the interlayer dielectric film 52. As shown in FIG. 16B, however, the protective film 53 can also be formed on the interlayer dielectric film 52.

### [5-2] Method of Manufacturing Carbon Nanotube Plug Interconnect

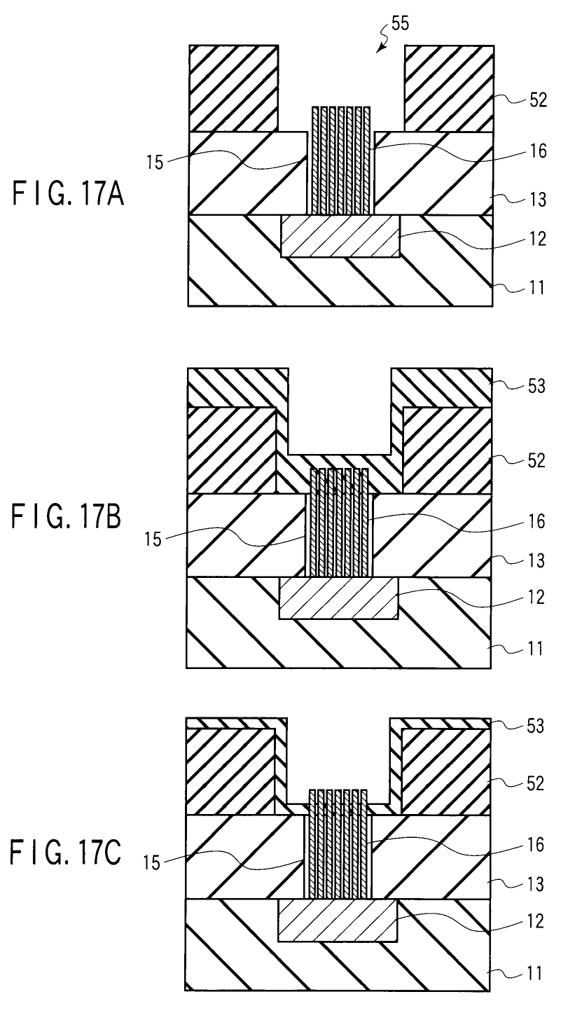

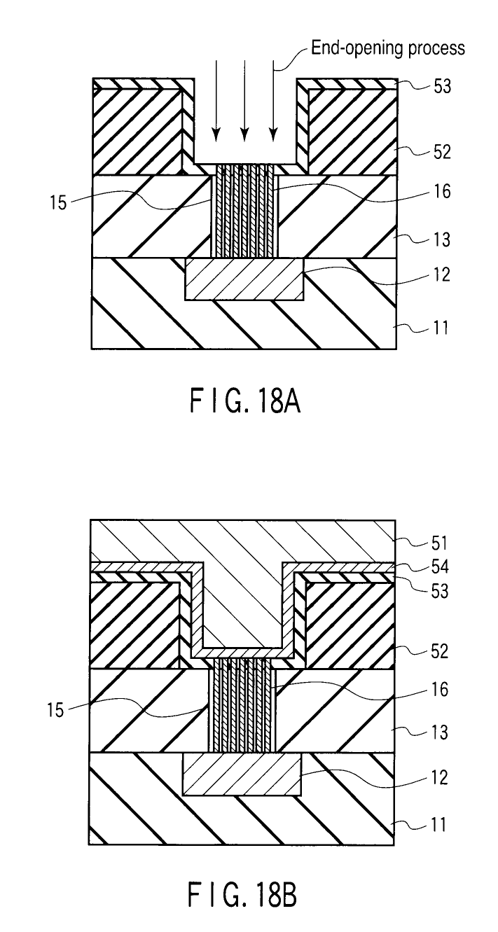

FIGS. 17A to 18B are sectional views showing a method of manufacturing the carbon nanotube plug interconnect of the fifth embodiment.

As shown in FIG. 17A, an interconnect trench is formed in an interlayer dielectric film 11, and a first interconnection layer 12 is formed in the interconnect trench. After that, interlayer dielectric films 13 and 52 are formed on the interlayer dielectric film 11 and first interconnection layer 12 by, e.g., CVD. A contact hole 15 and interconnect trench 55 are formed in the interlayer dielectric films 13 and 52 by lithography.

Then, carbon nanotubes 16 are formed on the first interconnection layer 12 in the contact hole 15. More specifically, the carbon nanotubes 16 are grown from the surface of the first interconnection layer 12 by the ordinary method until they protrude from the contact hole 15.

After that, as shown in FIG. 17B, a protective film 53 is formed by CVD on and between the carbon nanotubes 16 above the contact hole 15, and on the interlayer dielectric film 52. In this step, the protective film 53 enters and fills the spaces between the carbon nanotubes 16 above the contact hole 15 and near the opening of the contact hole 15. Thus, the protective film 53 and carbon nanotubes 16 protect the interior of the contact hole 15.

Subsequently, as shown in FIG. 17C, the ends of the carbon nanotubes 16 above the contact hole 15 are exposed by etching the protective film 53 by dry etching, e.g., RIE, such that the protective film 53 remains over the contact hole 15.

After that, as shown in FIG. 18A, plasma processing, e.g., RIE is performed on the carbon nanotubes 16 protruding from the protective film 53 in the interconnect trench 55, thereby removing the carbon nanotubes 16 protruding from the protective film 53, and performing an end-opening process of opening the ends of the carbon nanotubes 16. This end-opening process is preferably performed immediately before the next sputtering step, and can also be performed as pre-processing of the sputtering step.

Since the protective film 53 is filled between the carbon nanotubes 16 above the contact hole 15, it is possible to reduce the amount of energy line, chemical species, or radical entering the contact hole in the above-mentioned plasma processing. This makes it possible to prevent damage to the sidewalls of the carbon nanotubes 16 in the contact hole 15 and to the surface of the first interconnection layer 12 on the bottom of the contact hole.

Then, as shown in FIG. 18B, a barrier metal 54 is formed in the interconnect trench 55 and on the interlayer dielectric film 52 by, e.g., sputtering, and a Cu film 51 is formed on the barrier metal 54. The Cu film 51, barrier metal 54, and protective film 53 on the interlayer dielectric film 52 are polished by CMP, thereby forming the barrier metal 54 and second interconnection layer 51 in the interconnect trench 55, as shown in FIG. 16A. The protective film 53 may remain on the interlayer dielectric film 52, as shown in FIG. 16B.

### [5-3] Effects of Fifth Embodiment

In the manufacturing method of the fifth embodiment as has been explained above, the protective film 53 is filled between the carbon nanotubes 16 above the contact hole 15. Therefore, the amount of energy line, chemical species, or radical entering the contact hole can be reduced during the etching process and end-opening process of the carbon nanotubes 16. This makes it possible to prevent damage to the sidewalls of the carbon nanotubes 16 in the contact hole 15 and to the surface of the first interconnection layer 12 on the bottom of the contact hole. Consequently, it is possible to prevent electrical defects of the plug interconnect having the carbon nanotubes 16, thereby improving the electrical connection between the first interconnection layer 12 and second interconnection layer 51.

### [6] Sixth Embodiment

In the sixth embodiment, an example in which an insulating film as a stopper film is formed on an interlayer dielectric film having a plug interconnect, another insulating film is formed as a protective film to be used when etching carbon nanotubes protruding from a contact hole, and a second interconnection layer is formed by the dual damascene method will be explained.

### [6-1] Carbon Nanotube Plug Interconnect

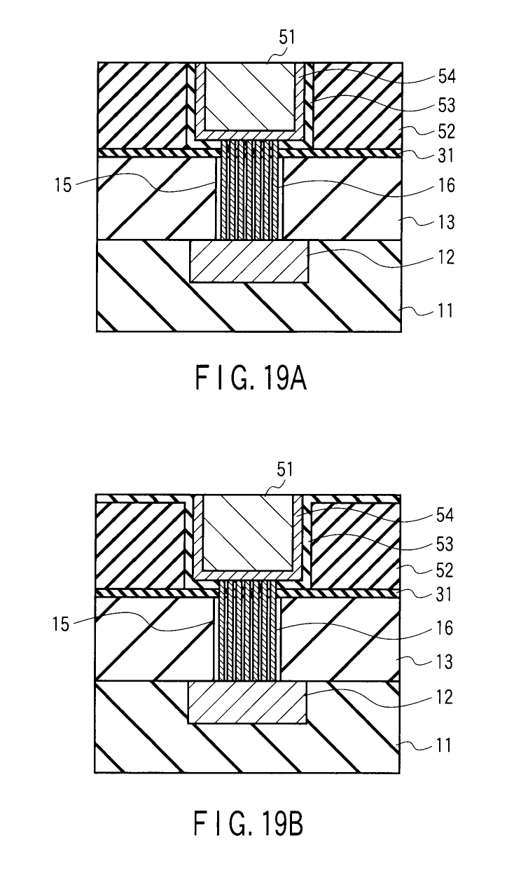

FIG. 19A is a sectional view showing a carbon nanotube plug interconnect of the sixth embodiment.

As shown in FIG. 19A, a first interconnection layer 12 is formed in an interlayer dielectric film 11. The interlayer dielectric film 11 is formed on a semiconductor substrate (not shown). The first interconnection layer 12 is buried in the interlayer dielectric film 11 so as to expose the surface. A barrier metal (not shown) is formed between the first interconnection layer 12 and the interlayer dielectric film 11 as needed.

An interlayer dielectric film 13 is formed on the interlayer dielectric film 11 and first interconnection layer 12. In the interlayer dielectric film 13 on the first interconnection layer 12, a contact hole 15 for electrically connecting a second interconnection layer 51 and the first interconnection layer 12 is formed. Carbon nanotubes 16 are formed in the contact hole 15. The carbon nanotubes 16 electrically connect the first interconnection layer 12 and second interconnection layer 51.

A stopper film 31 is formed on the interlayer dielectric film 13. The stopper film 31 is filled in the ends of the carbon nanotubes 16 on the side of the second interconnection layer 51, so as to fix the carbon nanotubes 16.

An interlayer dielectric film 52, e.g., SiO₂ is formed on the stopper film 31. An interconnect trench is formed in the interlayer dielectric film 52 over the contact hole 15. A protective film 53 is formed in this interconnect trench so as to cover it. The protective film 53 is filled between the carbon nanotubes 16 protruding from the contact hole 15.

A barrier metal 54 is formed on the protective film 53 in the interconnect trench so as to cover the protective film 53. In addition, the second interconnection layer 51 is formed on the barrier metal 54 in the interconnect trench. The barrier metal 54 is positioned between the second interconnection layer 51 and protective film 53, and prevents the diffusion of the material of the second interconnection layer 51 to the protective film 53 and the interlayer dielectric film 52.

Note that FIG. 19A shows an example in which the protective film 53 is not formed on the interlayer dielectric film 52, i.e., the protective film 53 does not remain on the interlayer dielectric film 52. As shown in FIG. 19B, however, the protective film 53 can also be formed on the interlayer dielectric film 52. Also, the stopper film 31 can also be formed to a position deeper than the bottom surface of the stopper film 31 existing between the interlayer dielectric film 13 and second interconnection layer 51. That is, the stopper film 31 may enter the contact hole 15.

### [6-2] Method of Manufacturing Carbon Nanotube Plug Interconnect

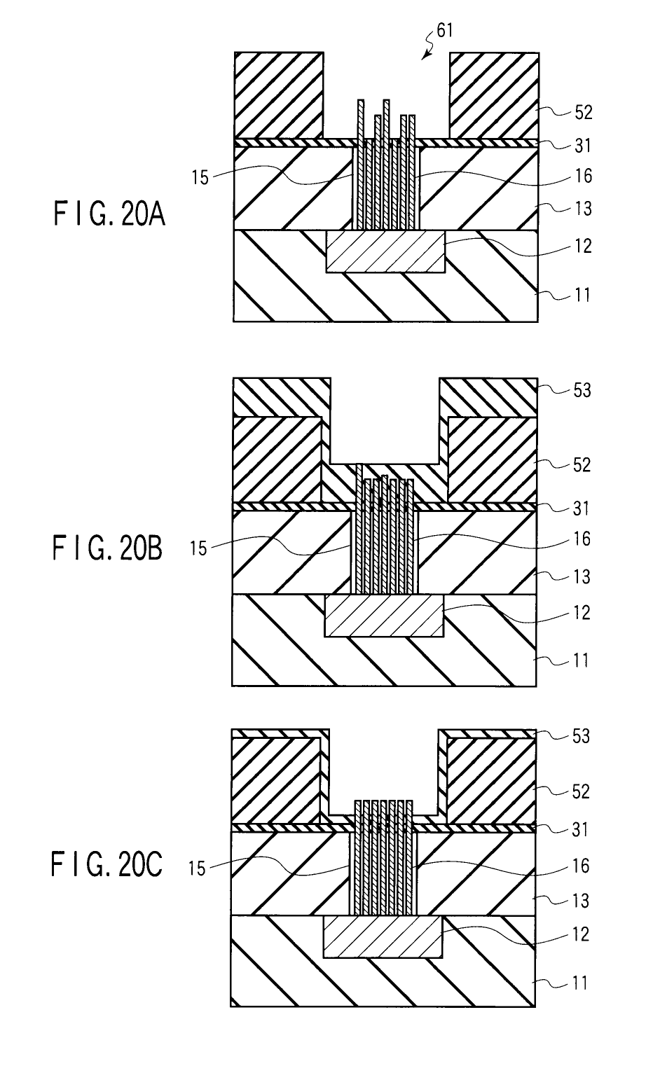

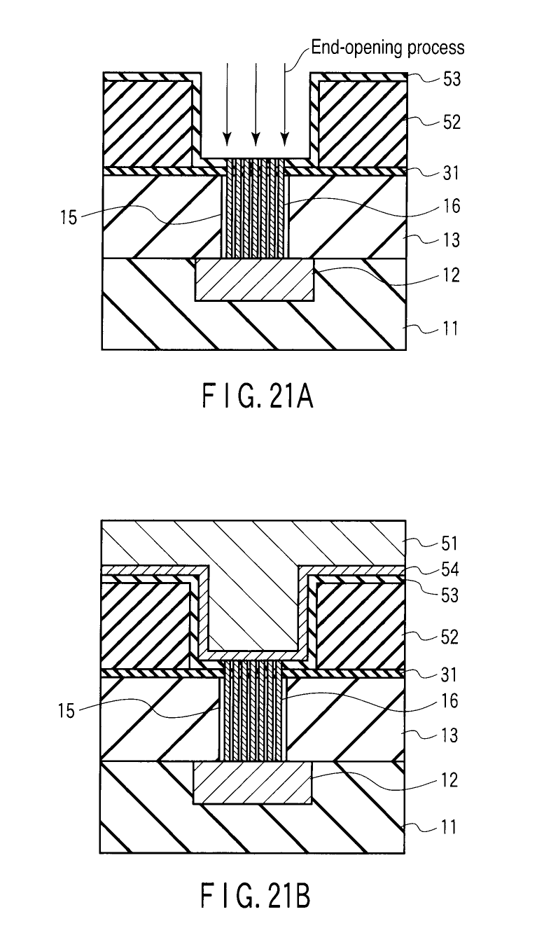

FIGS. 20A to 21B are sectional views showing a method of manufacturing the carbon nanotube plug interconnect of the sixth embodiment.

As shown in FIG. 20A, carbon nanotubes 16 are formed on a first interconnection layer 12 in a contact hole 15. A stopper film 31 is formed on an interlayer dielectric film 13 and between the carbon nanotubes 16 above the contact hole 15. An interlayer dielectric film 52 is formed on the stopper film 31 and carbon nanotubes 16 by CVD. In addition, an interconnect trench 61 is formed in the interlayer dielectric film 52 over the contact hole 15.

Then, as shown in FIG. 20B, a protective film 53 is formed by CVD on and between the carbon nanotubes 16 above the contact hole 15, on the stopper film 31, and on the interlayer dielectric film 52. In this step, the protective film 53 enters and fills the spaces between the carbon nanotubes 16 on the stopper film 31. Thus, the protective film 53 and stopper film 31 protect the interior of the contact hole 15.

Subsequently, as shown in FIG. 20C, the ends of the carbon nanotubes 16 above the contact hole 15 are exposed by etching the protective film 53 by dry etching, e.g., RIE, such that the protective film 53 remains on the stopper film 31.

After that, as shown in FIG. 21A, plasma processing, e.g., RIE is performed on the carbon nanotubes 16 protruding from the protective film 53 in the interconnect trench 61, thereby removing the carbon nanotubes 16 protruding from the protective film 53, and performing an end-opening process of opening the ends of the carbon nanotubes 16. This end-opening process is preferably performed immediately before the next sputtering step, and can also be performed as pre-processing of the sputtering step.

Since the protective film 53 and stopper film 31 are filled between the carbon nanotubes 16 above the contact hole 15, it is possible to reduce the amount of energy line, chemical species, or radical entering the contact hole in the above-mentioned plasma processing. This makes it possible to prevent damage to the sidewalls of the carbon nanotubes 16 in the contact hole 15 and to the surface of the first interconnection layer 12 on the bottom of the contact hole.

Then, as shown in FIG. 21B, a barrier metal 54 is formed in the interconnect trench 61 and on the interlayer dielectric film 52 by, e.g., sputtering, and a Cu film 51 is formed on the barrier metal 54. The Cu film 51, barrier metal 54, and protective film 53 on the interlayer dielectric film 52 are polished by CMP, thereby forming the barrier metal 54 and second interconnection layer 51 in the interconnect trench 61, as shown in FIG. 19A. The protective film 53 may remain on the interlayer dielectric film 52, as shown in FIG. 19B.

### [6-3] Effects of Sixth Embodiment

In the sixth embodiment as has been explained above, the protective film 53 and stopper film 31 are filled between the carbon nanotubes 16 above the contact hole 15. Therefore, the amount of energy line, chemical species, or radical entering the contact hole can be reduced during the etching process and end-opening process of the carbon nanotubes 16. This makes it possible to prevent damage to the sidewalls of the carbon nanotubes 16 in the contact hole 15 and to the surface of the first interconnection layer 12 on the bottom of the contact hole. Consequently, it is possible to prevent electrical defects of the plug interconnect having the carbon nanotubes 16, thereby improving the electrical connection between the first interconnection layer 12 and second interconnection layer 51.

In the embodiments, in a plug interconnect obtained by forming carbon nanotubes in a via hole or contact hole, those portions of the carbon nanotubes which have grown to protrude from the hole are surrounded by an insulating film, metal film, or the like, and the opening and its vicinity of the hole are protected as they are covered. This makes it possible to prevent the breakage of the carbon nanotubes themselves, the oxidation of an interconnect on the hole bottom, structural defects, and other damage, in later CMP, plasma processing, etching, and asking.

Each embodiment provides a carbon nanotube interconnect capable of obtaining a favorable electrical connection in a plug interconnect having carbon nanotubes, and a method of manufacturing the same.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A carbon nanotube interconnect comprising:
a first interconnection layer;
an interlayer dielectric film formed on the first interconnection layer;
a second interconnection layer formed on the interlayer dielectric film;
a contact hole formed in the interlayer dielectric film between the first interconnection layer and the second interconnection layer;
a plurality of carbon nanotubes formed in the contact hole, and the carbon nanotubes having a first end connected to the first interconnection layer and a second end connected to the second interconnection layer; and
a film formed between the interlayer dielectric film and the second interconnection layer, and having a portion filled between the second ends of the carbon nanotubes.

2. The interconnect of claim 1, wherein the portion of the film filled between the second ends enters to a position below the film between the interlayer dielectric film and the second interconnection layer.

3. The interconnect of claim 1, wherein the film fixes the carbon nanotubes.

4. The interconnect of claim 1, wherein the second ends of the carbon nanotubes protrude upward from the contact hole.

5. The interconnect of claim 4, wherein the film is positioned in a portion where the carbon nanotubes protrude upward from the contact hole.

6. The interconnect of claim 1, wherein the film comprises an insulting film.

7. The interconnect of claim 6, wherein the film contains at least one of SiN, SiC, and SiCN.

8. The interconnect of claim 1, further comprising a barrier metal film formed between the second interconnection layer, and the film and the carbon nanotubes.

9. A carbon nanotube interconnect comprising:
a first interconnection layer;
a first interlayer dielectric film formed on the first interconnection layer;
a second interlayer dielectric film formed on the first interlayer dielectric film;
a second interconnection layer formed in an interconnect trench of the second interlayer dielectric film;
a contact hole formed in the first interlayer dielectric film between the first interconnection layer and the second interconnection layer;
a plurality of carbon nanotubes formed in the contact hole, and the carbon nanotubes having a first end connected to the first interconnection layer and a second end connected to the second interconnection layer; and
a film formed between the first interlayer dielectric film and the second interconnection layer, and having a portion filled between the second ends of the carbon nanotubes.

10. The interconnect of claim 9, wherein the portion of the film filled between the second ends enters to a position below the film between the first interlayer dielectric film and the second interconnection layer.

11. The interconnect of claim 9, wherein the film fixes the carbon nanotubes.

12. The interconnect of claim 9, wherein the film comprises an insulting film.

13. The interconnect of claim 9, wherein the second ends of the carbon nanotubes protrude upward from the contact hole.

14. The interconnect of claim 9, further comprising a barrier metal film formed between the second interconnection layer, and the film, the carbon nanotubes, and the second interlayer dielectric film.

15. The interconnect of claim 14, further comprising a protective film formed between the barrier metal film, and the film, the carbon nanotubes, and the second interlayer dielectric film.

16. A method of manufacturing a carbon nanotube interconnect, comprising:
forming an interlayer dielectric film on a first interconnection layer;
forming a contact hole in the interlayer dielectric film on the first interconnection layer;
growing carbon nanotubes on the first interconnection layer in the contact hole, thereby forming the carbon nanotubes having ends protruding from the contact hole;
forming a film on the interlayer dielectric film and between the carbon nanotubes;
forming an insulating film on the film and the carbon nanotubes;
removing the insulating film on the film and the carbon nanotubes above the contact hole; and
forming a second interconnection layer on the carbon nanotubes.

17. The method of claim 16, wherein the film fixes the carbon nanotubes.

18. The method of claim 16, wherein in the removing the carbon nanotubes, the carbon nanotubes protruding upward from the film are removed.

19. The method of claim 16, further comprising an end-opening process of opening exposed ends of the carbon nanotubes, after the removing the carbon nanotubes.

20. The method of claim 19, wherein the end-opening process comprises one of a method of destroying the ends of the carbon nanotubes by irradiation with an energy line selected from the group consisting of a plasma, UV light, and an ion beam, and a method of processing the ends of the carbon nanotubes by a reaction with one of a chemical species and a radical of a material selected from the group consisting of oxygen, hydrogen, and fluorine.
